(19) United States
(12) Patent Application Publication
(10) Pub. No.: US 2011/0316609 A1
(43) Pub. Date: Dec. 29, 2011

(54) BIPOLAR JUNCTION TRANSISTOR TURN ON-OFF POWER CIRCUIT

(75) Inventor: ERIK J. CEGNAR, MOSCOW, ID (US)

(73) Assignee: IVUS INDUSTRIES, LLC, Moscow, ID (US)

(21) Appl. No.: 13/226,671

(22) Filed: Sep. 7, 2011

Related U.S. Application Data
(63) Continuation-in-part of application No. 12/510,841, filed on Jul. 28, 2009.
(60) Provisional application No. 61/084,029, filed on Jul. 28, 2008.

(51) Int. Cl. H03K 17/687

(52) U.S. Cl. 327/432

(57) ABSTRACT

An on-off power circuit connecting a voltage source to a digital system. The on-off power having a turn-on signal source, a control bipolar junction transistor, a switching bipolar junction transistor, a turn-off bipolar junction transistor, and a turn-off signal source. The circuit is activated by a turn-on signal and deactivated by a turn-off signal.

### PRIORITY/CROSS-REFERENCE TO RELATED APPLICATIONS

This application is a continuation-in-part of application Ser. No. 12/510,841, filed 28 Jul. 2009, which was a non-provisional of Application No. 61/084,029, filed 28 Jul. 2008, the disclosures of which are incorporated herein by reference.

### TECHNICAL FIELD

The disclosure generally relates to an electrical circuit that, from two separate signals, controls power to a system or circuit.

### BACKGROUND

The use of digital systems in consumer products is wide and growing. Systems are often turned on and off by means of a toggle switch where the system receives power when the switch is on and does not receive power when the switch is off. Systems may also employ a conventional flip-flop type circuit. A conventional flip-flop circuit is limited in the input voltage range and always consumes power, which is not desirable for battery-powered systems.

These two means for turning on or off systems (toggle switch, flip-flop type circuit) is limiting. Digital systems often need to perform processes after the user turns the system off. The toggle switch does not provide for an interim state before the power is turned off. Therefore, post processes cannot take place once the toggle switch is turned off. Also, it is beneficial that a system is able to use the power button as an input button with the initial button function being to turn the system on. The button can then be used as an input button to perform many functions including indicating to the system to turn itself off. Neither the toggle nor the flip-flop circuit can be used as an additional input button.

### SUMMARY OF THE DISCLOSURE

Several exemplary turn on-off power circuit for digital systems are described herein.

A first exemplary on-off power circuit for digital systems for coupling a voltage source to the digital system. The on-off power circuit comprising a turn-on signal source, a control bipolar junction transistor comprising a base, an emitter and a collector, a switching bipolar junction transistor comprising a base, an emitter and a collector, a turn-off bipolar junction transistor comprising a base, an emitter and a collector, and a turn-off signal source. The turn-on signal source is a means for activating having an open position and a closed position, wherein when in the closed position the means for activating provides a turn-on signal. The turn-on signal source generates a turn-on signal. The turn-off signal source generates a turn-off signal which turns on the turn-off bipolar junction transistor.

A second exemplary on-off power circuit for digital systems for coupling a voltage source to the digital system. The on-off power circuit comprising a turn-on signal source, a control bipolar junction transistor comprising a base, an emitter and a collector, a switching bipolar junction transistor comprising a base, an emitter and a collector, a turn-off bipolar junction transistor comprising a base, an emitter and a collector, and a turn-off signal source. The turn-on signal source is a means for activating having an open position and a closed position, wherein when in the closed position the means for activating provides a turn-on signal. The turn-on signal source generates a turn-on signal. The turn-off signal source generates a turn-off signal which turns on the turn-off bipolar junction transistor. The turn-on signal turns on the control bipolar junction transistor. The control bipolar junction transistor collector is coupled to the base of the switching bipolar junction transistor. The control bipolar junction transistor turns on the switching bipolar junction transistor when the control bipolar junction transistor is on. In the circuit, when the switching bipolar junction transistor is on, the voltage source is coupled to the digital system. The collector of the turn-off bipolar junction transistor is coupled to the base of the control bipolar junction transistor. The collector of the switching bipolar junction transistor is coupled to the base of the control bipolar junction transistor. In the circuit, when the turn-off bipolar junction transistor is on, the connection between the collector of the switching bipolar junction transistor and the base of the control bipolar junction transistor is shunted. In the circuit, when the control bipolar junction transistor is turned off, then the switching bipolar junction transistor is turned off and the voltage source is uncoupled from the digital system. In the circuit, when the turn-off bipolar junction transistor is on at the same time the turn-on signal is active, the control bipolar junction transistor remains on.

A third exemplary on-off power circuit for digital systems for coupling a voltage source to the digital system. The on-off power circuit comprising a turn-on signal source, a control bipolar junction transistor comprising a base, an emitter and a collector, a switching bipolar junction transistor comprising a base, an emitter and a collector, a turn-off bipolar junction transistor comprising a base, an emitter and a collector, and a turn-off signal source. The turn-on signal source is a means for activating having an open position and a closed position, wherein when in the closed position the means for activating provides a turn-on signal. The turn-on signal source generates a turn-on signal. The turn-off signal source generates a turn-off signal which turns on the turn-off bipolar junction transistor. The turn-on signal turns on the switching bipolar junction transistor. The collector of the switching bipolar junction transistor is coupled to the base of the control bipolar junction transistor so that upon the switching bipolar junction transistor being turned on, the control bipolar junction transistor is turned on. The collector of the turn-off bipolar junction transistor is coupled to the base of the control bipolar junction transistor. The collector of the switching bipolar junction transistor is coupled to the base of the control bipolar junction transistor. In the circuit, when the turn-off bipolar junction transistor is on, the connection between the collector of the switching bipolar junction transistor and the base of the control bipolar junction transistor is shunted. In the circuit, when the control bipolar junction transistor is turned off, then the switching bipolar junction transistor is turned off and the voltage source is uncoupled from the digital system. In the circuit, when the turn-off bipolar junction transistor is on at the same time the turn-on signal is active, the control bipolar junction transistor is turned off while the switching bipolar junction transistor remains on, wherein upon the turn-off bipolar junction transistor turning off while the turn-on signal is still active, the switching bipolar junction transistor turns the control bipolar junction transistor back on.

A fourth exemplary on-off power circuit for digital systems for coupling a voltage source to the digital system. The on-off power circuit comprising: a turn-on signal source, a control bipolar junction transistor comprising a base, an emitter and a collector, a switching bipolar junction transistor comprising a base, an emitter and a collector, a turn-off bipolar junction transistor comprising a base, an emitter and a collector, and a turn-off signal source. The turn-on signal source generates a turn-on signal. The turn-on signal turns on the control bipolar junction transistor. The control bipolar junction transistor collector is coupled to the base of the switching bipolar junction transistor. The control bipolar junction transistor turns on the switching bipolar junction transistor when the control bipolar junction transistor is on. In the circuit, when the switching bipolar junction transistor is on, the voltage source is coupled to the digital system.

A fifth exemplary on-off power circuit for digital systems for coupling a voltage source to the digital system. The on-off power circuit comprising a base, an emitter and a collector, a switching bipolar junction transistor comprising a base, an emitter and a collector, a turn-off bipolar junction transistor comprising a base, an emitter and a collector, and a turn-off signal source. The turn-on signal source generates a turn-on signal. The turn-on signal turns on the control bipolar junction transistor. The control bipolar junction transistor collector is coupled to the base of the switching bipolar junction transistor. The control bipolar junction transistor turns on the switching bipolar junction transistor when the control bipolar junction transistor is on. In the circuit, when the switching bipolar junction transistor is on, the voltage source is coupled to the digital system. The turn-off signal source generates a turn-off signal. The turn-off signal turns on the turn-off bipolar junction transistor. The collector of the turn-off bipolar junction transistor is coupled to the base of the control bipolar junction transistor. The collector of the switching bipolar junction transistor is coupled to the base of the control bipolar junction transistor. In the circuit, when the turn-off bipolar junction transistor is on, the connection between the collector of the switching bipolar junction transistor and the base of the control bipolar junction transistor is shunted. In the circuit, when the control bipolar junction transistor is turned off, then the switching bipolar junction transistor is turned off and the voltage source is uncoupled from the digital system.

A sixth exemplary on-off power circuit for digital systems for coupling a voltage source to the digital system. The on-off power circuit comprising a turn-on signal source, a control bipolar junction transistor comprising a base, an emitter and a collector, a switching bipolar junction transistor comprising a base, an emitter and a collector, a turn-off bipolar junction transistor comprising a base, an emitter and a collector, and a turn-off signal source. The turn-on signal source generates a turn-on signal. The turn-on signal turns on the switching bipolar junction transistor. The collector of the switching bipolar junction transistor is coupled to the base of the control bipolar junction transistor so that upon the switching bipolar junction transistor being turned on, the control bipolar junction transistor is turned on.

A seventh exemplary on-off power circuit for digital systems for coupling a voltage source to the digital system. The on-off power circuit comprising a turn-on signal source, a control bipolar junction transistor comprising a base, an emitter and a collector, a switching bipolar junction transistor comprising a base, an emitter and a collector, a turn-off bipolar junction transistor comprising a base, an emitter and a collector, and a turn-off signal source. The turn-on signal source generates a turn-on signal. The turn-on signal turns on the switching bipolar junction transistor. The collector of the switching bipolar junction transistor is coupled to the base of the control bipolar junction transistor so that upon the switching bipolar junction transistor being turned on, the control bipolar junction transistor is turned on. The turn-off signal source generates a turn-off signal. The turn-off signal turns on the turn-off bipolar junction transistor. The collector of the turn-off bipolar junction transistor is coupled to the base of the control bipolar junction transistor. The collector of the switching bipolar junction transistor is coupled to the base of the control bipolar junction transistor. In the circuit, when the turn-off bipolar junction transistor is on, the connection between the collector of the switching bipolar junction transistor and the base of the control bipolar junction transistor is shunted.

Additional understanding of the devices and methods contemplated and/or claimed by the inventors can be gained by reviewing the detailed description of exemplary devices and methods, presented below, and the referenced drawings.

### BRIEF DESCRIPTION OF THE DRAWINGS

FIG. 1 is a schematic view of a first exemplary turn on-off power circuit for digital systems.

FIG. 2 is a schematic view of a second exemplary turn on-off power circuit for digital systems.

FIG. 3 is a schematic view of a third exemplary turn on-off power circuit for digital systems

### DETAILED DESCRIPTION

The following description and the referenced drawings provide illustrative examples of that which the inventors regard as their invention. As such, the embodiments discussed herein are merely exemplary in nature and are not intended to limit the scope of the invention, or its protection, in any manner. Rather, the description and illustration of these embodiments serve to enable a person of ordinary skill in the relevant art to practice the invention.

The use of “e.g.,” “etc,” “for instance,” “in example,” and “or” and grammatically related terms indicates non-exclusive alternatives without limitation, unless otherwise noted. The use of “including” and grammatically related terms means “including, but not limited to,” unless otherwise noted. The use of the articles “a,” “an” and “the” are meant to be interpreted as referring to the singular as well as the plural, unless the context clearly dictates otherwise. Thus, for example, reference to “a bipolar junction transistor” includes two or more such bipolar junction transistors, and the like. The use of “coupled” means either a direct electrical connection between things that are connected, or an indirect electrical connection through one or more passive or active intermediary devices, unless the context clearly dictates otherwise. The use of “exemplary” means “an example of” and is not intended to convey a meaning of an ideal or preferred embodiment.

Disclosed is a turn-on circuit that is used to provide power to a system or other circuit when activated. The circuit is activated through activation of a means for activating, such as by depression of a momentary button or other similar device. The circuit is deactivated by a separate digital signal from said system or said other circuit and when deactivated no longer provides power to the system. During activation by means for activating, said turn-on circuit outputs a signal to a digital system indicating activation. The said turn-on circuit consumes no power until the means for activating is activated. The said turn-on circuit operates over a wide range or input voltages.

The said turn-on circuit provides two distinct advantages. First, it provides a method by which a system can turn itself off. Second, it allows a system's power button to be used as an input button as well. The ability of a system to turn itself off is advantageous because a system may receive an input to turn-off but may first need to perform a process before it powers down. Because said turn-on circuit can be used as a power turn-on button and a user input button, said turn-on circuit can be used to develop systems with advanced button input schemes and functionality.

An example of this functionality is a system operating one program that is only on when the button is depressed and turns off when it is no longer depressed. That same system, operating a different program, may stay on after one depression and release of the button, and enter a different functional mode temporarily if the button is depressed and held. The system would also then be capable of incrementing modes of operation for each button depression and then turn-off after all modes have been cycled through. The system would also be able to discern and perform functions based on multiple clicks, for example single, double, etc.

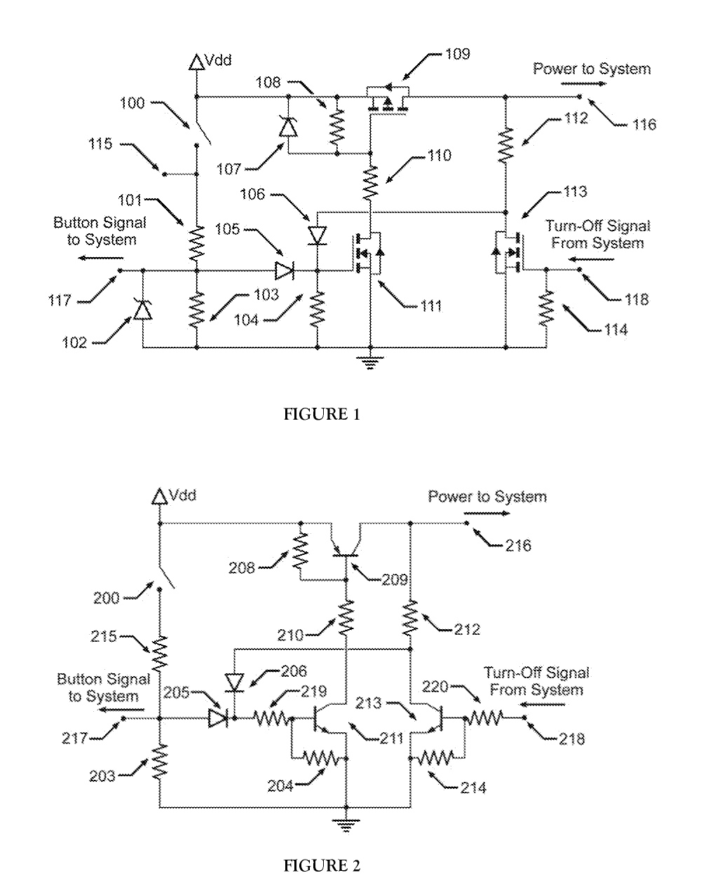

A first exemplary turn on-off power circuit for digital systems is illustrated in FIG. 1.

In the first illustrated embodiment, the circuit is activated by the depression of a momentary switch 100 or the application of a voltage to activation node 115 (the turn-on signal). Resistors 101 and 103 form a voltage divider, which acts to reduce the voltage over resistor 103. When the button is depressed or a voltage is applied to node 115, a current flows from a power source (Vdd) through resistor 101, diode 105, and resistor 104. A voltage is generated at the gate of mosfet 111. The gate voltage causes the mosfet 111 to conduct and current flows through resistor 108, resistor 110, and the mosfet 111. Because resistor 108 is significantly larger than resistor 110, the majority of the voltage drop is over resistor 108. This voltage causes the voltage Vsg of mosfet 109 to be greater than its threshold voltage. The mosfet 109 then conducts and provides power to a system at node 116.

When on, the mosfet 109 provides a voltage to the gate of mosfet 111, through resistor 112 and diode 106. This positive feedback system causes the circuit to latch and continue to be active after the momentary switch 100 is no longer depressed, or the voltage at node 115 is removed.

While the momentary switch 100 is depressed or a voltage is applied to node 115, there is an output voltage at node 117. This voltage indicates that the button is depressed or a voltage is being applied to node 115. Zener diode 102 ensures that the voltage at node 115 does not exceed a system's maximum input voltage specification. The diode 105 ensures that an output voltage at node 117 is not present once the momentary switch 100 is not depressed or once a voltage is not being provided to node 115.

When a voltage is applied to node 118, this causes mosfet 113 to conduct. This causes the voltage Vsg at the gate of mosfet 111 to drop below its threshold voltage. The mosfet 111 then turns off and stops conducting current. Once the mosfet stops conducting, the current through resistors 108 and 110 goes to zero, and the Vsg of mosfet 109 is then zero volts. This causes mosfet 109 to turn-off and therefore power is no longer provided to the system. After the circuit is deactivated, the voltage at node 118 may return to zero volts and the circuit will only be reactivated by depressing momentary switch 100 or applying a voltage to node 115.

In the event that a turn-off signal is applied to node 118 while the button is depressed or a voltage is applied to node 115, the circuit will remain active and continue supplying power to the system. In this scenario, the diode 106 prevents the mosfet 113 from pulling the gate of mosfet 111 down. Therefore, mosfet 111 remains on. If the turn-off signal is present at node 118 and the button discontinues being depressed or voltage at node 115 is removed, the circuit will immediately become deactivated and stop supplying power to the system at node 116.

Zener diode 107 and resistor 110 prevent the voltage Vsg of mosfet 109 from going beyond its maximum rated source-to-gate voltage. A zener diode is sometimes integrated into mosfets to protect the gate.

Resistors 104, 108, and 114 ensure that mosfets 111, 109, and 113 respectively remain off when a voltage is not applied from gate to source.

Referring now to FIG. 2, the second exemplary on-off power circuit for digital systems is shown. The second exemplary on-off power circuit for digital systems is similar to the first exemplary on-off power circuit for digital systems illustrated in FIG. 1 and described above, except as detailed below.

In comparison to the first exemplary on-off power circuit for digital systems, the second exemplary on-off power circuit for digital systems utilizes bipolar junction transistors instead of mosfets. A bipolar junction transistor is a three-terminal electronic device constructed of doped semiconductor material and may be used in amplifying or switching applications. The three-terminals comprising a base, a collector and an emitter. If both the base-emitter junction and the collector-base junction are reverse biased, the operating mode is called a cut-off mode, and the bipolar junction transistor operates as an open switch. If both the base-emitter junction and the collector-base junction are forward biased, the operating mode is called a saturation mode, and the bipolar junction transistor operates as a closed switch. When the bipolar junction transistor is in saturation mode, the transistor is fully on, and the base current is at its maximum.

The second exemplary on-off power circuit for digital systems is for connecting a voltage source to a digital system. The second exemplary on-off power circuit comprising: a turn-on signal source, a control bipolar junction transistor, a switching bipolar junction transistor, a turn-off bipolar junction transistor, and a turn-off signal source.

The second exemplary on-off power circuit for digital systems having an active high switch signal in order to energize (turn-on) the circuit. The circuit is activated by a turn-on signal from the turn on signal source. The turn-on signal for turning on the control bipolar junction transistor 211.

The turn-on signal may be provided by a means for activating (the turn-on signal source). FIG. 2 illustrates the means for activating comprising a momentary switch 200. The means for activating having two positions: an open position, and a closed position. In the closed position, the turn-on signal is provided to the circuit. Other means for activating are also envisioned, for instance the application of an external voltage signal that is pulled high (or substantially greater than zero volts) at a node (such as is illustrated in the first exemplary turn on-off power circuit for digital systems as node 115 in FIG. 1).

Resistors 215 and 203 form a voltage divider, which acts to reduce the voltage over resistor 203. When the circuit is activated by applying the turn-on signal, current flows from a power source (Vdd) through resistor 215, diode 205, resistor 219, and resistor 204. The voltage applied to the base-emitter junction of control bipolar junction transistor 211 causes the maximum base current to flow, which turns the control bipolar junction transistor 211 on (saturation mode).

When the control bipolar junction transistor 211 is turned on, current flows through control bipolar junction transistor 211, resistor 210 and resistor 208. Resistors 208 and 210 have been selected to drive bipolar junction transistor 209 into saturation and “on,” while limiting the base current to a safe level This voltage drives switching bipolar junction transistor 209 into saturation mode, turning switching bipolar junction transistor 209 on, and resulting in power being supplied to the system at node 216.

When in its saturation mode (on), the switching bipolar junction transistor 209 provides a voltage to the base of control bipolar junction transistor 211, through resistor 212, diode 206, and resistor 219. This positive feedback system causes the circuit to latch and continue to be active after the means for activating is no longer active (e.g., the momentary switch 200 is no longer depressed (open)).

While the turn-on signal is active, there is an output voltage at node 217 which indicates that the turn-on signal is present. Diode 205 ensures that an output voltage at node 217 is only present when the turn-on signal is active.

When a turn-off signal, with an appropriate voltage, is generated by the turn-off signal source and applied to the circuit, for instance at node 218, turn-off bipolar junction transistor 213 will be driven into saturation mode and turned on. Turning turn-off bipolar junction transistor 213 on drives the base current of control bipolar junction transistor 211 to zero, and control bipolar junction transistor 211 enters cut-off mode. When control bipolar junction transistor 211 is off (cut-off mode), control bipolar junction transistor 211 stops conducting current (cut-off mode), and the current through resistor 208 and resistor 210 goes to zero amps, which turns switching bipolar junction transistor 209 off (cut-off mode). When switching bipolar junction transistor 209 is off, power is no longer available to the system at node 216 and the circuit is deactivated.

After the circuit is deactivated, the voltage at node 218 may return to zero volts, and the circuit will only be reactivated by the presence of the turn-on signal (e.g., depression (closing) of momentary switch 200).

In the event that a turn-off signal is applied to node 218 while a turn-on signal is present, the circuit will remain active and continue supplying power to the system at node 216. In this scenario, the diode 206 is reverse biased and prevents the turn-off bipolar junction transistor 213 from turning off control bipolar junction transistor 211, as the base current to keep control bipolar junction transistor 211 turned on is from the power source (Vdd) through resistor 215, diode 205, and resistor 219, thereby resulting in the control bipolar junction transistor 211 remaining on.

If the turn-off signal is present at node 218 and turn-on signal is not active, the circuit will immediately become deactivated, and power to the system will no longer be available at node 216.

Resistors 219, 210 and 220 limit the base current of their bipolar junction transistors 211, 209, and 213. Resistors 204, 208, and 214 stabilize the base of their bipolar junction transistors 211, 209, and 213.

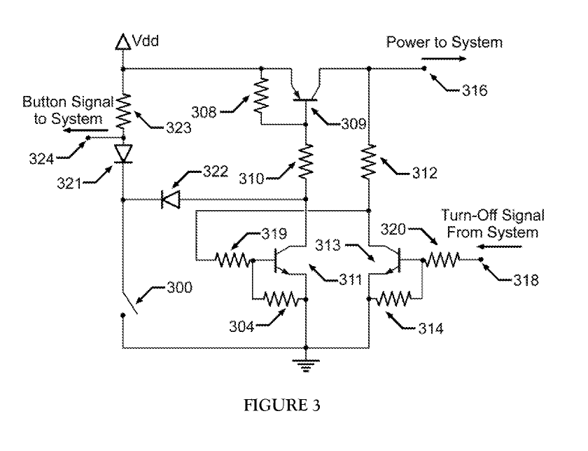

Referring now to FIG. 3, the third exemplary on-off power circuit for digital systems is illustrated. The third exemplary on-off power circuit for digital systems is similar to the first and second exemplary on-off power circuit for digital systems illustrated in FIGS. 1 and 2 described above, except as detailed below.

The third exemplary on-off power circuit for digital systems for connecting a voltage source to a digital system. The third exemplary on-off power circuit comprising: a turn-on signal source, a control bipolar junction transistor, a switching bipolar junction transistor, a turn-off bipolar junction transistor, and a turn off signal source.

In the third exemplary on-off power circuit for digital systems, illustrated is a bipolar junction transistor equivalent circuit where a turn-on signal is active low in order to energize (turn-on) the circuit. The circuit is activated by an active low turn-on signal (the turn-on signal pulled low (or substantially lower than voltage Vdd)) generated by a turn-on signal source. The turn-on signal source can comprise a means for activating (e.g., a turn-on signal caused by the depression of a momentary switch 300), or an external signal. The momentary switch 300 having two positions: an open position, and a closed position.

When the circuit is activated by presence of the low turn-on signal, a current flows from a power source (Vdd) through resistors 308, 310 and 232, diodes 321 and 322, and switch 300. This results in the base-emitter junction and the emitter-base junction of the switching bipolar junction transistor 309 becoming forward biased. This is because resistors 308 and 310 have been selected to drive bipolar junction transistor 309 into saturation and on while limiting the base current to a safe level. This turns the switching bipolar junction transistor 309 on (saturated mode). When switching bipolar junction transistor 309 is turned on (saturated), power is available to a system at node 316.

When switching bipolar junction transistor 309 is on (saturated), a voltage to the base of control bipolar junction transistor 311 is provided from node 316 through resistors 312 and 319. This positive feedback system keeps control bipolar junction transistor 311 turned on (saturated), and causes the circuit to latch and continue to be active after low turn-on signal is no longer active.

While the low turn-on signal is active, the voltage at node 324 drops. This voltage drop indicates that the low turn-on signal is active. Diode 322 ensures that an output voltage at node 324 is not pulled down through control bipolar junction transistor 311 once the low turn-on signal is no longer active.

When an appropriate turn-off signal voltage (from a turn-off signal source) is applied to node 318, turn-off bipolar junction transistor 313 is turned on (saturated). When turn-off bipolar junction transistor 313 is on, the base emitter junction of control bipolar junction transistor 311 is no longer forward biased, base current goes to zero, and control bipolar junction transistor 311 switches off (cut-off mode). Once control bipolar junction transistor 311 is off, the current through resistors 308 and 310 goes to zero amps, the base current of switching bipolar junction transistor 309 goes to zero, and switching bipolar junction transistor 309 turns off (cut-off mode). With switching bipolar junction transistor 309 off, no power is available to the system at node 316. After the circuit is deactivated, the voltage at node 318 may return to zero volts and the circuit will only be reactivated by an active low turn-on signal.

In the event that a turn-off signal is applied to node 318 while a low turn-on signal is active, the circuit will remain active and continue supplying power to the system at node 316. In this scenario, turn-off bipolar junction transistor 313 is turned on when the turn-off signal is applied to node 318. When turn-off bipolar junction transistor 313 is turned on, the base-emitter junction of control bipolar junction transistor 311 is no longer forward biased, base current goes to zero, and control bipolar junction transistor 311 switches off (cut off mode). While control bipolar junction transistor 311 is turned off, in this condition with both turn-on and turn-off conditions present, the base current for switching bipolar junction transistor 309 flows through resistor 310, diode 322 and switch 300, keeping switching bipolar junction transistor 309 turned on and power will be available to the system at node 316.

If the turn-off signal is active at node 318, and low turn-on signal is not active, the circuit will immediately become deactivated and power will no longer be available to the system at node 316.

Resistors 319, 310 and 320 limit the base current of their bipolar junction transistors 311, 309, and 313. Resistors 304, 308, and 314 stabilize the base of their bipolar junction transistors 311, 309, and 313.

In FIG. 2, switch signal from node 217 provides an active high signal to a digital system indicated by a button depression. In FIG. 3, switch signal at node 324 provides the exact same functionality, except that it is active low instead of active high.

In the fourth exemplary on-off power circuit for digital systems (not illustrated), an active low button signal circuit is accomplished using mosfets.

It is noted that all structure and features of the various described and illustrated embodiments can be combined in any suitable configuration for inclusion in a circuit according to a particular embodiment. For example, a circuit according a particular embodiment can include neither, one, or both of mosfets and bipolar junction transistors described above.

Any suitable materials can be used to form the various components of the circuit, and a skilled artisan will be able to select appropriate materials for a circuit according to a particular embodiment based on various considerations, including the system within which the circuit is intended to be used, and the environment within which the circuit/system is intended to be used.

The foregoing detailed description provides exemplary embodiments of the invention and includes the best mode for practicing the invention. The description and illustration of these embodiments is intended only to provide examples of the invention, and not to limit the scope of the invention, or its protection, in any manner.

What is claimed is:

1. An on-off power circuit coupling a voltage source to a digital system, the on-off power circuit comprising, a turn-on signal source, a control bipolar junction transistor comprising a base, an emitter and a collector, a switching bipolar junction transistor comprising a base, an emitter and a collector, a turn-off bipolar junction transistor comprising a base, an emitter and a collector, and a turn-off signal source.

2. The on-off power circuit of claim 1, wherein the turn-on signal source is a means for activating.

3. The on-off power circuit of claim 2, wherein the means for activating has an open position and a closed position, wherein when in said closed position said means for activating provides a turn-on signal.

4. The on-off power circuit of claim 3, wherein said means for activating comprises a momentary switch.

5. The on-off power circuit of claim 1, wherein said turn-on signal source generates a turn-on signal.

6. The on-off power circuit of claim 5, wherein said turn-on signal turns on said control bipolar junction transistor.

7. The on-off power circuit of claim 6, wherein said control bipolar junction transistor collector is coupled to the base of the switching bipolar junction transistor, and wherein said control bipolar junction transistor turns on said switching bipolar junction transistor when said control bipolar junction transistor is on.

8. The on-off power circuit of claim 7, wherein when said switching bipolar junction transistor is on, the voltage source is coupled to the digital system.

9. The on-off power circuit of claim 5, wherein said turn-on signal turns on said switching bipolar junction transistor.

10. The on-off power circuit of claim 9, wherein the collector of said switching bipolar junction transistor is coupled to the base of said control bipolar junction transistor so that upon said switching bipolar junction transistor being turned on, said control bipolar junction transistor is turned on.

11. The on-off power circuit of claim 1, wherein said turn-off signal source generates a turn-off signal.

12. The on-off power circuit of claim 11, wherein said turn-off signal turns on said turn-off bipolar junction transistor.

13. The on-off power circuit of claim 12, wherein the collector of said turn-off bipolar junction transistor is coupled to the base of the control bipolar junction transistor, wherein the collector of said switching bipolar junction transistor is coupled to the base of said control bipolar junction transistor, and wherein when said turn-off bipolar junction transistor is on, the connection between the collector of said switching bipolar junction transistor and the base of said control bipolar junction transistor is shunted.

14. The on-off power circuit of claim 13, wherein when the control bipolar junction transistor is turned off, then the switching bipolar junction transistor is turned off and the voltage source is uncoupled from the digital system.

15. The on-off power circuit of claim 12, wherein when said turn-off bipolar junction transistor is on at the same time said turn-on signal is active, the control bipolar junction transistor remains on.

16. The on-off power circuit of claim 12, wherein when said turn-off bipolar junction transistor is on at the same time said turn-on signal is active, the control bipolar junction transistor is turned off while the switching bipolar junction transistor remains on, wherein upon said turn-off bipolar junction transistor turning off while said turn-on signal is still active, said switching bipolar junction transistor turns said control bipolar junction transistor back on.

17. An on-off power circuit coupling a voltage source to a digital system, the on-off power circuit comprising, a turn-on signal source, a control bipolar junction transistor comprising a base, an emitter and a collector, a switching bipolar junction transistor comprising a base, an emitter and a collector, a turn-off bipolar junction transistor comprising a base, an emitter and a collector, and a turn-off signal source; wherein said turn-on signal source generates a turn-on signal; wherein said turn-on signal turns on said control bipolar junction transistor; wherein said control bipolar junction transistor collector is coupled to the base of the switching bipolar junction transistor, wherein said control bipolar junction transistor turns on said switching bipolar junction transistor when said control bipolar junction transistor is on; and wherein when said switching bipolar junction transistor is on, the voltage source is coupled to the digital system.

18. The on-off power circuit of claim 17, wherein said turn-off signal source generates a turn-off signal; wherein said turn-off signal turns on said turn-off bipolar junction transistor; wherein the collector of said turn-off bipolar junction transistor is coupled to the base of the control bipolar junction transistor; wherein the collector of said switching bipolar junction transistor is coupled to the base of said control bipolar junction transistor; wherein when said turn-off bipolar junction transistor is on, the connection between the collector of said switching bipolar junction transistor and the base of said control bipolar junction transistor is shunted; and wherein when the control bipolar junction transistor is turned off, then the switching bipolar junction transistor is turned off and the voltage source is uncoupled from the digital system.

19. An on-off power circuit coupling a voltage source to a digital system, the on-off power circuit comprising, a turn-on signal source, a control bipolar junction transistor comprising a base, an emitter and a collector, a switching bipolar junction transistor comprising a base, an emitter and a collector, a turn-off bipolar junction transistor comprising a base, an emitter and a collector, and a turn-off signal source; wherein said turn-on signal source generates a turn-on signal; wherein said turn-on signal turns on said switching bipolar junction transistor; and wherein the collector of said switching bipolar junction transistor is coupled to the base of said control bipolar junction transistor so that upon said switching bipolar junction transistor being turned on, said control bipolar junction transistor is turned on.

20. The on-off power circuit of claim 19, wherein said turn-off signal source generates a turn-off signal; wherein said turn-off signal turns on said turn-off bipolar junction transistor; wherein the collector of said turn-off bipolar junction transistor is coupled to the base of the control bipolar junction transistor; wherein the collector of said switching bipolar junction transistor is coupled to the base of said control bipolar junction transistor; and wherein when said turn-off bipolar junction transistor is on, the connection between the collector of said switching bipolar junction transistor and the base of said control bipolar junction transistor is shunted.
